(19) United States
(12) Patent Application Publication
(10) Pub. No.: US 2013/0213299 A1
(43) Pub. Date: Aug. 22, 2013

(54) LIQUID TANK AND THIN FILM DEPOSITION APPARATUS USING THE SAME

(71) Applicants: FU-SHUN HU, Taoyuan County (TW); CHIH-CHIEH CHU, New Taipei City (TW); HENG LIU, Sunnyvale, CA (US)

(72) Inventors: FU-SHUN HU, Taoyuan County (TW); CHIH-CHIEH CHU, New Taipei City (TW); HENG LIU, Sunnyvale, CA (US)

(73) Assignee: PINECONE MATERIAL INC., Taipei City (TW)

(21) Appl. No.: 13/599,599

(22) Filed: Aug. 30, 2012

(30) Foreign Application Priority Data
Feb. 17, 2012 (TW) 101105326

(51) Int. Cl. C23C 16/00; F17D 1/00

(52) U.S. Cl. 118/712; 118/724; 137/565.17

(57) ABSTRACT

A liquid tank includes at least one main tank, a supplemental tank and a transmission module. The main tank is supplied with a first liquid. The supplemental tank is supplied with a second liquid. The transmission module is connected between the supplemental tank and the at least one main tank. The transmission module is configured to supply the second liquid into the main tank while the first liquid in the main tank is lowered down to a first position, and to stop supplying the second liquid into the main tank while the first liquid in the main tank is raised up to the first position. A thin film deposition apparatus using the aforementioned liquid tank is also provided.

### TECHNICAL FIELD

The present invention relates to a semiconductor manufacturing process and apparatus, and more particularly to a liquid tank and a thin deposition apparatus using the same.

### BACKGROUND

Thin Film Deposition, used in a wide range of surface process applications, amongst which are decorations, cutlery, knifes, tools, molds, and semiconductor components, refers to a manufacturing process for growing a homogeneous or heterogeneous materials film on a variety of materials, super-hard alloys, ceramic materials, and wafer substrates so as to make the products have beautiful appearance, grind-resistant, heat-resistant, and corrosion-resistant features. Thin film deposition, based on it whether or not contains a chemical reaction mechanism in the deposition process, can be divided into Physical Vapor Deposition (PVD) and the Chemical Vapor Deposition (CVD).

Based on the deposition techniques and deposition parameters, the deposited thin films can have a single crystal, polycrystalline, or amorphous structure. Single crystal thin film deposition is particularly important in the manufacturing process of integrated circuits, known as epitaxy. Compared to a wafer substrate, epitaxial semiconductor thin films have advantages such as: through directing doping donors or acceptors in the deposition process, the dopant profile can be precisely controlled without introducing oxygen and carbon impurities.

Metal-Organic Chemical Vapor Deposition (MOCVD) is a thin-film deposition technology that first uses a carrier gas to carry gas reactants or precursors as they enter the chamber with a wafer, and converting the reactants (usually gas) into a solid-state resultant deposited on a surface of the wafer through chemical reactions of a single or several kinds of gas triggered by a high temperature after heating the wafer and the gas close to the wafer in a particular manner.

The reaction sources of an MOCVD system can be divided into two categories, the first is a metal organic (MO) reaction source and the second is a hydride gas reaction source. The metal organic reaction source is stored in a sealed container; and through connecting two pipes of the sealed container to that of an MOCVD machine and supplying the carrier gas into the sealed container via one pipe, the saturated vapor of the reaction source is brought into a reaction chamber of the MOCVD machine via another pipe. The hydride gas is stored in an airtight cylinder, and the flow of hydride gas into the reaction chamber is controlled via a pressure regulator and a flow controller.

Please refer to FIG. 1, which is a schematic view of a conventional liquid tank. As shown, to retain the metal organic compound at a certain temperature so that the vapor pressure of organic metal compound gas is controllable, a bottle 12 supplied with organic metal compound liquid 10 is placed in a liquid tank 14 thereby having a constant temperature. However, the liquid tank 14 may have a temperature change and consequently the vapor pressure of organic metal compound gas is affected after a period while cooling liquid 16 in the liquid tank 14 evaporates. Conventionally, supplement of the cooling liquid 16 is performed manually; and thus, the complexity of MOCVD operation increases.

### SUMMARY OF EMBODIMENTS

Therefore, one object of the present invention is to provide a liquid tank capable of automatically supplying liquid to a main tank(s) and thereby retaining the liquid level of the liquid at a predetermined height, thus the associated reaction source can have a more stable temperature.

Another object of the present invention is to provide a thin film deposition apparatus with an easy-operation feature.

An embodiment of the present invention provides a liquid tank, which includes at least one main tank, a supplemental tank and a transmission module. The main tank is supplied with a first liquid. The supplemental tank is supplied with a second liquid. The transmission module is connected between the supplemental tank and the main tank. The transmission module is configured to supply the second liquid into the main tank while the first liquid in the main tank is lowered down to a first position, and to stop supplying the second liquid into the main tank while the first liquid in the main tank is raised up to the first position.

In an embodiment of the present invention, the transmission module includes a pipe unit having a liquid inlet and at least one liquid outlet. The liquid inlet is connected to the supplemental tank. The liquid outlet is correspondingly connected to the main tank, and each liquid outlet is disposed at the first position of the corresponding main tank.

In an embodiment of the present invention, the second liquid in the supplemental tank has a liquid level higher than the first liquid in the main tank.

In an embodiment of the present invention, a bottom of the supplemental tank has a height higher than a liquid level of the first liquid in the main tank.

In an embodiment of the present invention, the supplemental tank is a sealed tank.

In an embodiment of the present invention, the first and second liquids have the same ingredients.

In an embodiment of the present invention, the transmission module includes a pipe unit, at least one liquid level measurement mechanism and at least one transmission unit. The pipe unit has a liquid inlet and at least one liquid outlet. The liquid inlet is connected to the supplemental tank. The liquid outlet is connected to the corresponding main tank. The liquid level measurement mechanism is corresponding to the main tank and each liquid level measurement mechanism is configured to detect the liquid level of the first liquid in the corresponding main tank. The transmission unit is disposed on a liquid transmission path in the pipe unit. Each liquid level measurement mechanism triggers, in response to a detection of the first liquid in the main tank having a liquid level lowered down to the first position, the transmission unit to transmit the second liquid from the supplemental tank into the main tank; and each liquid level measurement mechanism controls, in response to a detection of the first liquid in the main tank having a liquid level raised up to a second position, the transmission unit to stop transmitting the second liquid.

In an embodiment of the present invention, the liquid level measurement mechanism includes a liquid level measurement pipe and a sensor. The liquid level measurement pipe is communicable with the corresponding main tank. The sensor is disposed next to the liquid level measurement pipe and electrically connected to the corresponding transmission unit. The sensor is configured to, in response to a detection of the first liquid in the liquid level measurement pipe having a liquid level lowered down to the first position, issue a first signal to trigger the corresponding transmission unit to transmit the second liquid. The sensor is configured to, in response to a detection of the first liquid in the liquid level measurement pipe having a liquid level raised up to the second position, issue a second signal to control the corresponding transmission unit to stop transmitting the second liquid.

In an embodiment of the present invention, the liquid level measurement mechanism includes a floating ball. The floating ball is linked to the corresponding transmission unit. The corresponding transmission unit is triggered to transmit the second liquid when the floating ball is lowered down to the first position; and the corresponding transmission unit is controlled to stop transmitting the second liquid when the floating ball is raised up to the second position

In an embodiment of the present invention, the second position is higher than or equal to the first position.

In an embodiment of the present invention, the transmission unit includes a motor, a solenoid valve or a pump.

The present invention further provides a thin film deposition apparatus, which includes a bottle, a process chamber, a communication pipe and the aforementioned liquid tank. The bottle is supplied with a reaction source and immersed in the liquid tank. The communication pipe is communicable between the bottle and the process chamber, and configured to transmit the reaction source into the process chamber.

In an embodiment of the present invention, the reaction source is a metal organic reaction source.

Summarily, because the liquid tank according to the present invention is capable of automatically supplying liquid to the main tank(s) and thereby retaining the liquid level of the liquid at a predetermined height, the associated reaction source can have a more stable temperature and consequently the associated thin film deposition apparatus according to the present invention can have an easy-operation feature.

### BRIEF DESCRIPTION OF THE DRAWINGS

The above embodiments will become more readily apparent to those ordinarily skilled in the art after reviewing the following detailed description and accompanying drawings as below.

FIG. 1 is a schematic view of a conventional liquid tank.

FIG. 2 is a schematic view of a thin film deposition apparatus in accordance with a first embodiment of the present invention.

FIG. 3 is a schematic view of a liquid tank in accordance with a second embodiment of the present invention.

FIG. 4 is a schematic view of a liquid tank in accordance with a third embodiment of the present invention.

FIG. 5 is a schematic view of a liquid tank in accordance with a fourth embodiment of the present invention.

### DETAILED DESCRIPTION OF PREFERRED EMBODIMENTS

The disclosure will now be described more specifically with reference to the following embodiments. It is to be noted that the following descriptions of preferred embodiments are presented herein for purposes of illustration and description only. It is not intended to be exhaustive or to be limited to the precise form disclosed.

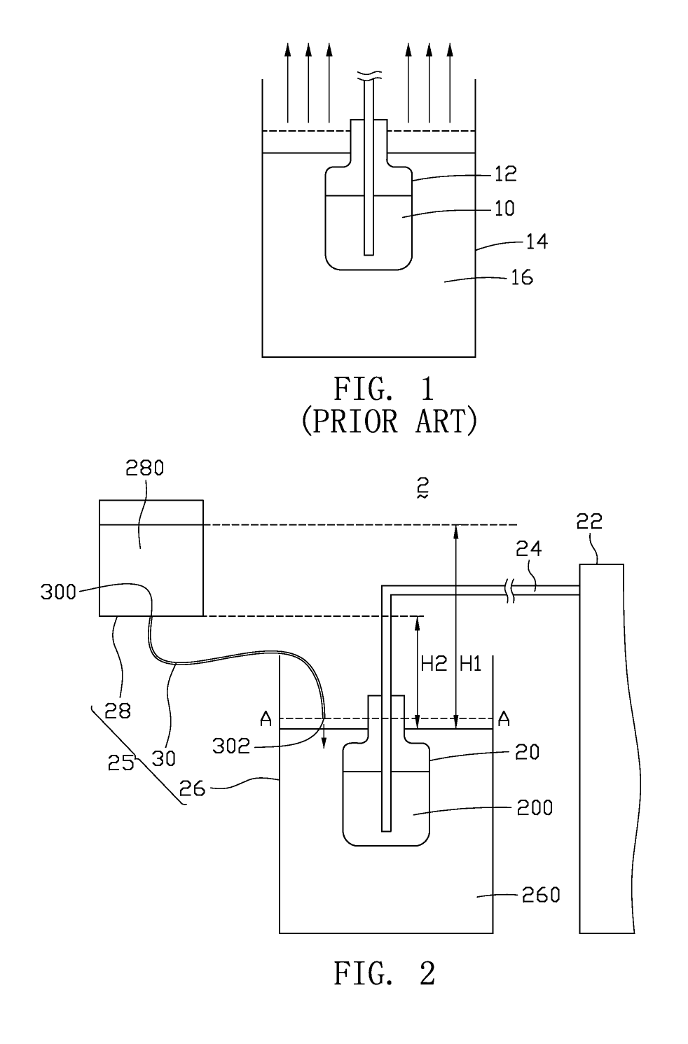

FIG. 2 is a schematic view of a thin film deposition apparatus 2 in accordance with a first embodiment of the present invention. As shown, the thin film deposition apparatus 2 in this embodiment includes a bottle 20, a process chamber 22, a communication pipe 24, and a liquid tank 25. The bottle 20 is supplied with a reaction source 200 and immersed in the liquid tank 25. The communication pipe 24, communicable between the bottle 20 and the process chamber 22, is configured to transmit the vaporous reaction source 200 into the process chamber 22. In this embodiment, the reaction source 200 is a metal organic reaction source, such as trimethylgallium (TMGa), trimethylaluminum (TMAl), trimethylindium (TMIn), Bis(cyclopentadienyl)magnesium (Cp2Mg), etc. In addition, the bottle 20 is, for example, a sealed stainless steel tank (e.g., a cylinder bubbler).

The liquid tank 25 includes a main tank 26, a supplemental tank 28, and a transmission module 30. The main tank 26 is supplied with a first liquid 260, and the bottle 20 is immersed in the main tank 26. The supplemental tank 28 is supplied with a second liquid 280; wherein the first liquid 260 and the second liquid 280 have the same ingredient. The transmission module 30 is connected between the supplemental tank 28 and the main tank 26, through which the second liquid 280 can be transmitted from the supplemental tank 28 into the main tank 26. In this embodiment, the first liquid 260 and the second liquid 280 are, for example, a coolant composed of about 50% water and 50% ethylene glycol (e.g., antifreeze); and thus, the first liquid 260 and the second liquid 280 can be prevented from freezing in the liquid tank 25.

In this embodiment, the transmission module 30 is, for example, a pipe unit and includes a liquid inlet 300, which is connected to the supplemental tank 28, and a liquid outlet 302, which is connected to the main tank 26. Preferably, the liquid inlet 300 is connected to a bottom of the supplemental tank 28. The liquid outlet 302 is disposed in the first position (indicated with a horizontal line A-A) of the main tank 26. The supplemental tank 28 is a sealed tank, and the second liquid 280 therein can automatically flow into the main tank 26 through the transmission module 30 while the first liquid 260 in the main tank 26 has a liquid level lower than or equal to the first position A-A. Specifically, while the first liquid 260 in the main tank 26 has a liquid level higher than or equal to the first position A-A, air is blocked from entering into the sealed supplemental tank 28 and, accordingly, the second liquid 280 cannot be pushed out from the supplemental tank 28 by the air. Alternatively, while the first liquid 260 in the main tank 26 has a liquid level lower than the first position A-A (as illustrated in FIG. 2), the air can enter into the supplemental tank 28 through the transmission module 30 and thereby simultaneously push a portion of the second liquid 280 into the main tank 26; wherein the second liquid 280 will not stop flowing into the main tank 26 until the first liquid 260 in the main tank 26 has a liquid level higher than or equal to the first position A-A.

In this embodiment, the second liquid 280 in the supplemental tank 28 is configured to have a liquid level higher than that of the first liquid 260 in the main tank 26; in other words, the height difference H1, between the liquid level of the second liquid 280 in the supplemental tank 28 and the liquid level of the first liquid 260 in the main tank 26, is configured to be greater than zero. Thus, the first liquid 260 in the main tank 26 can, due to the siphon principle, be prevented from flowing back into the supplemental tank 28. Preferably, the supplemental tank 28 is configured to have its bottom with a height greater than the height of the liquid level of the first liquid 260 in the main tank 26; in other words, the height difference H2, between the bottom of the second liquid 280 in the supplemental tank 28 and the liquid level of the first liquid 260 in the main tank 26, is configured to be greater than zero.

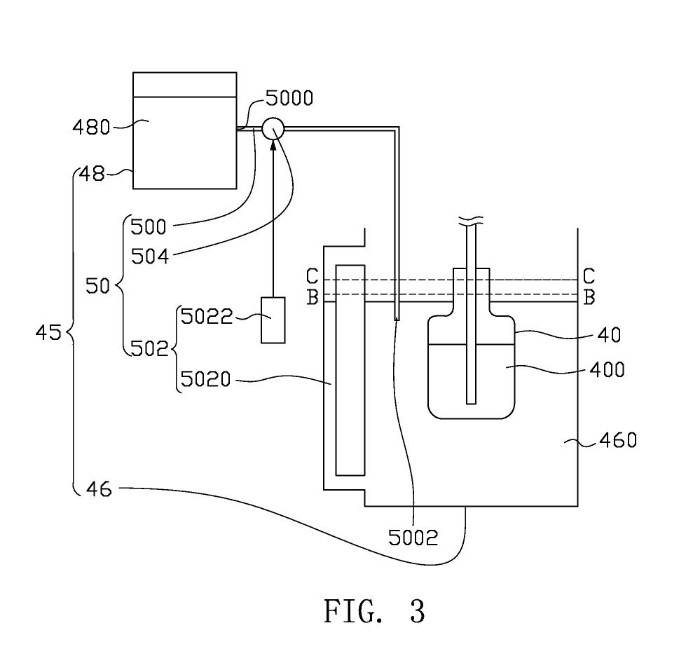

FIG. 3 is a schematic view of a liquid tank 45 in accordance with a second embodiment of the present invention. Specifically, the liquid tank 45 in this embodiment is applicable for use with a thin film deposition apparatus; and the process chamber communicable with the bottle 40 is not shown in FIG. 3. In addition, the bottle 40 is supplied with a reaction source 400 and immersed in the liquid tank 45; and the bottle 40 and the reaction source 400 in this embodiment are the same as the bottle 20 and the reaction source 200 in the first embodiment, respectively, and no unnecessary detail is given here. As shown in FIG. 3, the liquid tank 45 in this embodiment includes a main tank 46, a supplemental tank 48 and a transmission module 50. The main tank 46 is supplied with a first liquid 460, and the bottle 40 is specifically immersed in the main tank 46. The supplemental tank 48 is supplied with a second liquid 480; wherein the first liquid 460 and the second liquid 480 in this embodiment have ingredients same as the first liquid 260 and the second liquid 280 in the first embodiment; and no unnecessary detail is given here. The transmission module 50 is connected between the supplemental tank 48 and the main tank 46, through which the second liquid 480 can be transmitted from the supplemental tank 48 into the main tank 46.

Moreover, the transmission module 50 includes a pipe unit 500, a liquid level measurement mechanism 502, and a transmission unit 504. The pipe unit 500 has a liquid inlet 5000, which is connected to the supplemental tank 48, and a liquid outlet 5002, which is connected to the main tank 46. The liquid level measurement mechanism 502 is applicable for use with the main tank 46 and is configured to detect the liquid level of the first liquid 460 in the main tank 46. The transmission unit 504 is disposed on a liquid transmission path in the pipe unit 500. Specifically, the liquid level measurement mechanism 502 is configured to, in response to a detection of the first liquid 460 in the main tank 46 having a liquid level lowered down to a first position (indicated with a horizontal line B-B, as illustrated in FIG. 3), trigger the transmission unit 504 so as to transmit the second liquid 480 from the supplemental tank 48 into the main tank 46. Alternatively, the liquid level measurement mechanism 502 is configured to, in response to a detection of the first liquid 460 in the main tank 46 having a liquid level raised up to a second position (indicated with a horizontal line C-C), control the transmission unit 504 to stop transmitting the second liquid 480 from the supplemental tank 48 into the main tank 46. In addition, as illustrated in FIG. 3, the second position C-C is higher than the first position B-B.

Moreover, in this embodiment, the liquid level measurement mechanism 502 includes a liquid level measurement pipe 5020 and a sensor 5022. The liquid level measurement pipe 5020 is communicable with the main tank 46. The sensor 5022, disposed next to the liquid level measurement pipe 5020 and electrically connected to the transmission unit 504, is configured to detect the liquid level of the first liquid 460 in the main tank 46. Specifically, the sensor 5022 is configured to, in response to a detection of the first liquid 460 in the liquid level measurement pipe 5020 having a liquid level lowered down to the first position B-B, issue a first signal for the triggering of the transmission unit 504, and consequently the second liquid 480 is transmitted from the supplemental tank 48 into the main tank 46. Alternatively, the sensor 5022 is configured to, in response to a detection of the first liquid 460 in the liquid level measurement pipe 5020 having a liquid level raised up to the second position C-C, issue a second signal for controlling the transmission unit 504 to stop transmitting the second liquid 480 from the supplemental tank 48 into the main tank 46. In addition, the transmission unit 504 is, for example but without limitation, a motor, a solenoid valve or a pump.

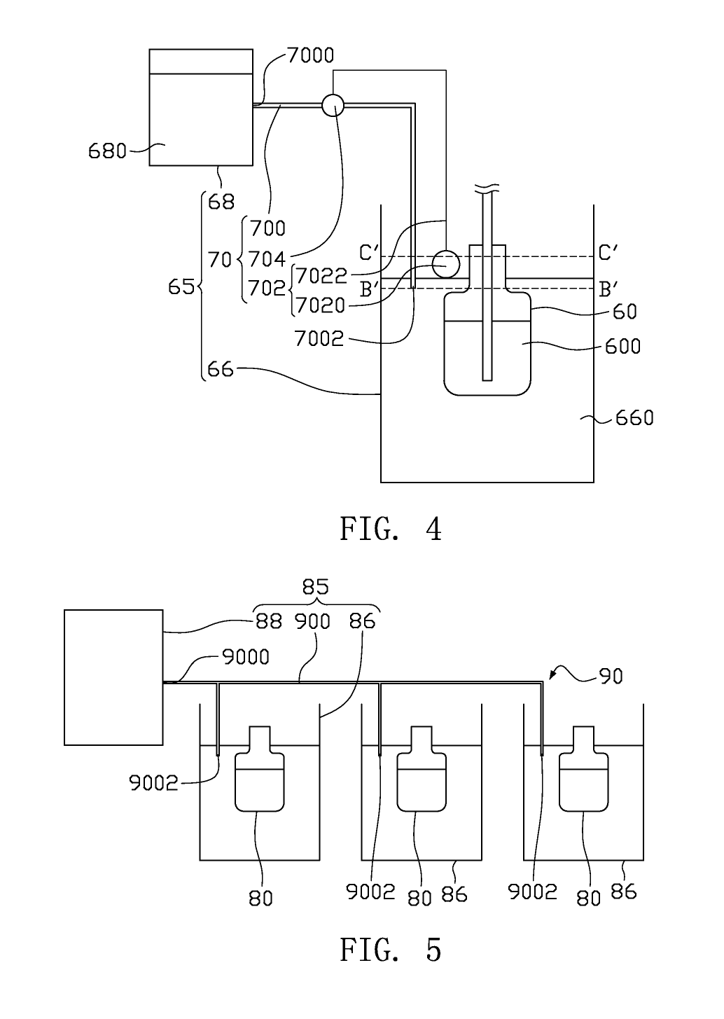

FIG. 4 is a schematic view of a liquid tank 65 in accordance with a third embodiment of the present invention. Specifically, the liquid tank 65 in this embodiment is applicable for use with a thin film deposition apparatus; and the process chamber communicable with the bottle 60 is not shown in FIG. 4. In addition, the bottle 60 is supplied with a reaction source 600 and immersed in the liquid tank 65; and the bottle 60 and the reaction source 600 in this embodiment are the same with the bottle 20 and the reaction source 200 in the first embodiment, respectively, and no unnecessary detail is given here. As shown in FIG. 4, the liquid tank 65 in this embodiment includes a main tank 66, a supplemental tank 68 and a transmission module 70. The main tank 66 is supplied with a first liquid 660, and the bottle 60 is specifically immersed in the main tank 66. The supplemental tank 68 is supplied with a second liquid 680. The first liquid 660 and the second liquid 680 in this embodiment have ingredients same as the first liquid 260 and the second liquid 280 in the first embodiment; and no unnecessary detail is given here. The transmission module 70 is connected between the supplemental tank 68 and the main tank 66, and through which the second liquid 680 can be transmitted from the supplemental tank 68 into the main tank 66.

Moreover, the transmission module 70 includes a pipe unit 700, a liquid level measurement mechanism 702 and a transmission unit 704. The pipe unit 700 has a liquid inlet 7000, which is connected to the supplemental tank 68, and a liquid outlet 7002, which is connected to the main tank 66. As illustrated in FIG. 4, a first position is indicated with a horizontal line B′-B′, a second position is indicated with a horizontal line C′-C′, and the second position C′-C′ is higher than the first position B′-B′. Compared with the second embodiment, the liquid level measurement mechanism 702 includes a floating ball 7020, which is linked to the transmission unit 704 through a linkage 7022. Specifically, the floating ball 7020 is configured to, when being lowered down to a first position B′-B′, drive the linkage 7022 to trigger the transmission unit 704 so as to transmit the second liquid 680 from the supplemental tank 68 into the main tank 66. Alternatively, the floating ball 7020 is configured to, when raised up to the second position C′-C′, drive the linkage 7022 to stop transmitting the second liquid 680 from the supplemental tank 68 into the main tank 66. Specifically, the transmission unit 704 is, for example, a valve.

The aforementioned embodiments each are exemplified by supplying the second liquid from the supplemental tank into one single main tank; however, it is to be noted that the present invention is not limited to a specific number of the main tanks. In other words, the number of main tanks in each aforementioned embodiment can be more than one. Accordingly, the second liquid can be supplied into these individual main tanks through the pipe unit. An embodiment exemplified by transmitting a liquid from one supplemental tank into a plurality of main tanks will be described in the following description with a reference associated figures.

FIG. 5 is a schematic view of a liquid tank 85 in accordance with a fourth embodiment of the present invention. Specifically, the liquid tank 85 in this embodiment is applicable for use with a thin film deposition apparatus; and the associated process chamber and the communicable pipe communicable with the bottles 80 are not shown in FIG. 5. In this embodiment, the liquid tank 85 includes a plurality of main tanks 86, and the bottles 80 supplied with a reaction source are immersed in the respective main tanks 86. The transmission module 90 includes a pipe unit 900. The pipe unit 900 has a liquid inlet 9000, which is connected to the supplemental tank 88, and a liquid outlet 9002, which is connected to each main tank 86. In addition, it is noted that the transmission module 90 may further include the liquid level measurement mechanism and the transmission unit disclosed in the second or third embodiments; and it is understood that each main tank 86 is corresponding to one liquid level measurement mechanism and one transmission unit.

In summary, because the liquid tank according to the present invention is capable of automatically supplying liquid to the main tank(s) and thereby retaining the liquid level of the liquid at a predetermined height, the associated reaction source can have a more stable temperature and consequently the associated thin film deposition apparatus according to the present invention can have an easy-operation feature.

While the disclosure has been described in terms of what is presently considered to be the most practical and preferred embodiments, it is to be understood that the disclosure needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A liquid tank, comprising:
at least one main tank supplied with a first liquid;
a supplemental tank supplied with a second liquid; and
a transmission module, connected between the supplemental tank and the main tank, configured to supply the second liquid into the main tank while the first liquid in the main tank is lowered down to a first position, and to stop supplying the second liquid into the main tank while the first liquid in the main tank is raised up to the first position.

2. The liquid tank according to claim 1, wherein the transmission module comprises a pipe unit having a liquid inlet and at least one liquid outlet, the liquid inlet is connected to the supplemental tank, the liquid outlet is correspondingly connected to the main tank, and the liquid outlet is disposed at the first position of the corresponding main tank.

3. The liquid tank according to claim 2, wherein the second liquid in the supplemental tank has a liquid level higher than the first liquid in the main tank.

4. The liquid tank according to claim 2, wherein a bottom of the supplemental tank has a height higher than a liquid level of the first liquid in the main tank.

5. The liquid tank according to claim 2, wherein the supplemental tank is a sealed tank.

6. The liquid tank according to claim 1, wherein the first liquid and the second liquid have the same ingredients.

7. The liquid tank according to claim 1, wherein the transmission module comprises:
a pipe unit having a liquid inlet and at least one liquid outlet, wherein the liquid inlet is connected to the supplemental tank, and the liquid outlet is correspondingly connected to the main tank;
at least one liquid level measurement mechanism corresponding to the main tank, being configured to detect the liquid level of the first liquid in the corresponding main tank; and
at least one transmission unit disposed on a liquid transmission path in the pipe unit,
wherein the liquid level measurement mechanism triggers, in response to a detection of the first liquid in the corresponding main tank having a liquid level lowered down to the first position, the transmission unit to transmit the second liquid from the supplemental tank into the corresponding main tank; and the liquid level measurement mechanism controls, in response to a detection of the first liquid in the corresponding main tank having the liquid level raised up to a second position, the transmission unit to stop transmitting the second liquid.

8. The liquid tank according to claim 7, wherein the liquid level measurement mechanism comprises:
a liquid level measurement pipe communicable with the corresponding main tank; and
a sensor disposed next to the liquid level measurement pipe and electrically connected to the corresponding transmission unit,
wherein the sensor is configured to, in response to a detection of the first liquid in the liquid level measurement pipe having a liquid level lowered down to the first position, issue a first signal to trigger the corresponding transmission unit to transmit the second liquid; and the sensor is configured to, in response to a detection of the first liquid in the liquid level measurement pipe having a liquid level raised up to the second position, issue a second signal to control the corresponding transmission unit to stop transmitting the second liquid.

9. The liquid tank according to claim 7, wherein the liquid level measurement mechanism comprises a floating ball linked to the corresponding transmission unit, the corresponding transmission unit is triggered to transmit the second liquid when the floating ball is lowered down to the first position; and the corresponding transmission unit is controlled to stop transmitting the second liquid when the floating ball is raised up to the second position.

10. The liquid tank according to claim 7, wherein the transmission unit comprises a motor, a solenoid valve or a pump.

11. A thin film deposition apparatus, comprising:
a bottle supplied with a reaction source;
a process chamber;
a communication pipe, communicable between the bottle and the process chamber, configured to transmit the reaction source into the process chamber; and
a liquid tank, the bottle being immersed in the liquid tank, the liquid tank comprising:
at least one main tank supplied with a first liquid;
a supplemental tank supplied with a second liquid; and
a transmission module, connected between the supplemental tank and the main tank, configured to supply the second liquid into the main tank while the first liquid in the main tank is lowered down to a first position, and to stop supplying the second liquid into the main tank while the first liquid in the main tank is raised up to the first position.

12. The thin film deposition apparatus according to claim 11, wherein the transmission module comprises a pipe unit having a liquid inlet and at least one liquid outlet, the liquid inlet is connected to the supplemental tank, the liquid outlet is correspondingly connected to the main tank, and the liquid outlet is disposed at the first position of the corresponding main tank.

13. The thin film deposition apparatus according to claim 11, wherein the second liquid in the supplemental tank has a liquid level higher than the first liquid in the main tank.

14. The thin film deposition apparatus according to claim 11, wherein a bottom of the supplemental tank has a height higher than a liquid level of the first liquid in the main tank.

15. The thin film deposition apparatus according to claim 12, wherein the supplemental tank is a sealed tank.

16. The thin film deposition apparatus according to claim 11, wherein the first liquid and the second liquid have the same ingredients.

17. The thin film deposition apparatus according to claim 11, wherein the transmission module comprises:
a pipe unit having a liquid inlet and at least one liquid outlet, wherein the liquid inlet is connected to the supplemental tank, the liquid outlet is correspondingly connected to the main tank;
at least one liquid level measurement mechanism corresponding to the main tank, being configured to detect the liquid level of the first liquid in the corresponding main tank; and
at least one transmission unit disposed on a liquid transmission path in the pipe unit,
wherein the liquid level measurement mechanism triggers, in response to a detection of the first liquid in the corresponding main tank having a liquid level lowered down to the first position, the transmission unit to transmit the second liquid from the supplemental tank into the corresponding main tank; and each liquid level measurement mechanism controls, in response to a detection of the first liquid in the corresponding main tank having the liquid level raised up to a second position, the transmission unit to stop transmitting the second liquid.

18. The thin film deposition apparatus according to claim 17, wherein the liquid level measurement mechanism comprises:
a liquid level measurement pipe communicable with the corresponding main tank; and
a sensor disposed next to the liquid level measurement pipe and electrically connected to the corresponding transmission unit,
wherein the sensor is configured to, in response to a detection of the first liquid in the liquid level measurement pipe having a liquid level lowered down to the first position, issue a first signal to trigger the corresponding transmission unit to transmit the second liquid; and the sensor is configured to, in response to a detection of the first liquid in the liquid level measurement pipe having the liquid level raised up to the second position, issue a second signal to control the corresponding transmission unit to stop transmitting the second liquid.

19. The thin film deposition apparatus according to claim 17, wherein the liquid level measurement mechanism comprises a floating ball linked to the corresponding transmission unit, the transmission unit is triggered to transmit the second liquid when the floating ball is lowered down to the first position, and the transmission unit is controlled to stop transmitting the second liquid when the floating ball is raised up to the second position.

20. The thin film deposition apparatus according to claim 17, wherein the transmission unit comprises a motor, a solenoid valve or a pump.
